(19) United States
(12) Patent Application Publication
(10) Pub. No.: US 2015/0027756 A1
(43) Pub. Date: Jan. 29, 2015

(54) CIRCUIT BOARD STRUCTURE FOR HIGH FREQUENCY SIGNALS

(71) Applicant: KINSUS INTERCONNECT TECHNOLOGY CORP., Taoyuan (TW)

(72) Inventors: Jun-Chung Hsu, Taoyuan County (TW); Yu-Hui Wu, Kaohsiung City (TW)

(73) Assignee: KINSUS INTERCONNECT TECHNOLOGY CORP., Taoyuan (TW)

(21) Appl. No.: 13/948,274

(22) Filed: Jul. 23, 2013

(51) Int. Cl. H05K 1/02

(52) U.S. Cl. CPC H05K 1/0237
USPC 174/255; 174/250

(57) ABSTRACT

A circuit board structure for high frequency signals includes a substrate and an electrical conductive circuit layer formed on the substrate. The conductive circuit layer includes circuit patterns and connection pads. The circuit pattern includes a base part with a shape of a rectangular block and a circular top part with a hemispherical shape provided on the base part. The circular top part can be modified by a circular bottom part embedded in the dielectric plastic film. Alternatively, a double layer structure with the circular top and bottom parts is formed such that the surface of the circuit pattern is provided with hemispheres to strengthen the reflection, thereby overcoming the problem of signal concentration due to the rectangular structure or the issue of signal attenuation due to surface roughness.

### BACKGROUND OF THE INVENTION

1. Field of the Invention

The present invention generally relates to a circuit board structure for high frequency signals, and more specifically to a circuit board structure with arc circuit patterns to reduce the transmission attenuation of high frequency signal.

2. The Prior Arts

With the advanced progress in the electronic products and the technique of the semiconductor industry, the circuit density and the transmission speed of signals have become much higher such that the demand for the application of high frequency and high speed has greatly increased. FIG. 1A shows a cross-sectional view of a circuit board structure for high frequency signals of the prior arts includes a substrate 100 and an electrical conductive circuit layer 11 formed on the substrate 100. The electrical conductive circuit layer 11 has circuit patterns 13 and connection pads 15. The electrical conductive circuit layer 11 is usually formed by electroplating so as to enhance its reliability. Thus, the surface of the substrate 100 needs to be roughened. Alternatively, the substrate 100 is stacked with an electroplating seed layer (not shown) and after forming the electrical conductive circuit layer 11, the seed layer is then removed. As a result, it is possible to roughen both the upper and lower surfaces 17 of the circuit patterns 13 and the connection pads 15. Though the roughened surfaces do help the adhesion between the adjacent layers, it is possible to attenuate the strength of high frequency signals at high speed because of many spike ends formed therein.

Moreover, to overcome the issue of roughened surfaces, FIG. 1B illustrates another example of the circuit board structure of the prior arts. As shown in FIG. 1B, the electrical conductive circuit layer 11 is embedded in the dielectric plastic film 120, and the circuit patterns 13 and the connection pads 15 are exposed to an exterior of the surface of the dielectric plastic film 120. This circuit pattern 13 has a rectangular cross section and still has the problem of signal concentration at the spike ends.

Therefore, it is crucially urgent to provide a new circuit board structure for high frequency signals to meet the requirements of the current and future electronic devices by modifying the structure of the electrical circuit patterns so as to solve the issue of high frequency signal transmission at high speed.

### SUMMARY OF THE INVENTION

A primary objective of the present invention is to provide a circuit board structure for high frequency signals, including a substrate and an electrical conductive circuit layer formed on the substrate. The conductive circuit layer has a plurality of circuit patterns and a plurality of connection pads. The circuit patterns are electrically connected to the connection pads. One primary feature of the present invention is that each circuit pattern includes a base part with a shape of rectangular block and a circular top part with a hemispherical shape provided on the base part. The circular top part is incorporated with the base part as an integrated body, and the circuit circularity of the circuit pattern is 25˜60%.

Another objective of the present invention is to provide a circuit board structure, which is modified from the above circuit board structure by replacing the circular top part with the circular bottom part and embedding the electrical conductive circuit layer in the dielectric plastic layer. The circular bottom part is formed by placing the circular top part upside down. Further, the two aspects are combined such that the circuit board structure has the circular top part and the circular bottom part. The circular bottom part and the base part are embedded in the dielectric plastic film and the circular top part projects from the surface of the dielectric plastic film.

Therefore, the surface of the circuit pattern is provided with hemispheres, which strengthens the reflection so as to solve the problem of signal concentration or signal attenuation, thereby being suitably applied to the field of signal transmission of high frequency at high speed.

### BRIEF DESCRIPTION OF THE DRAWINGS

The present invention can be understood in more detail by reading the subsequent detailed description in conjunction with the examples and references made to the accompanying drawings, wherein:

FIG. 1A is a cross sectional view illustrating one example of a circuit board structure in the prior arts;

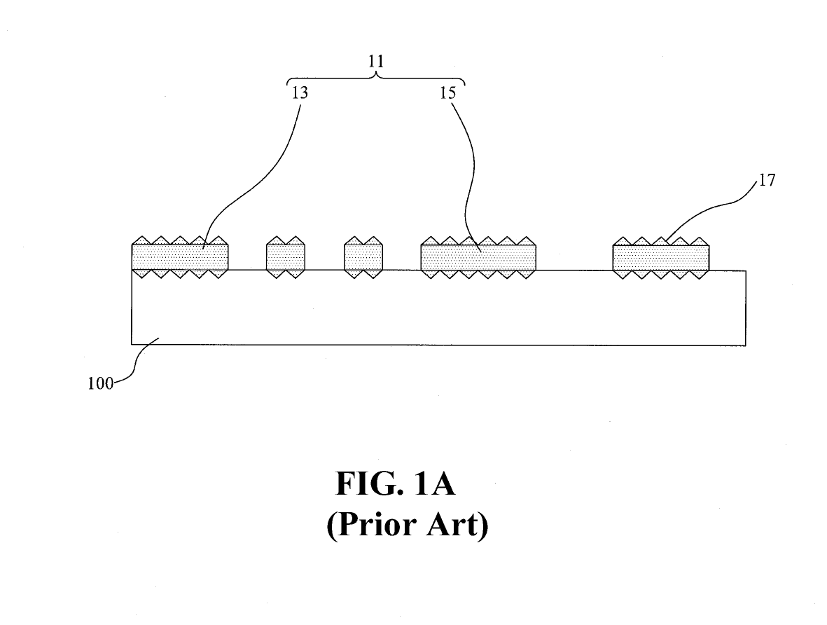

FIG. 1B is a cross sectional view illustrating another example of the circuit board structure in the prior arts;

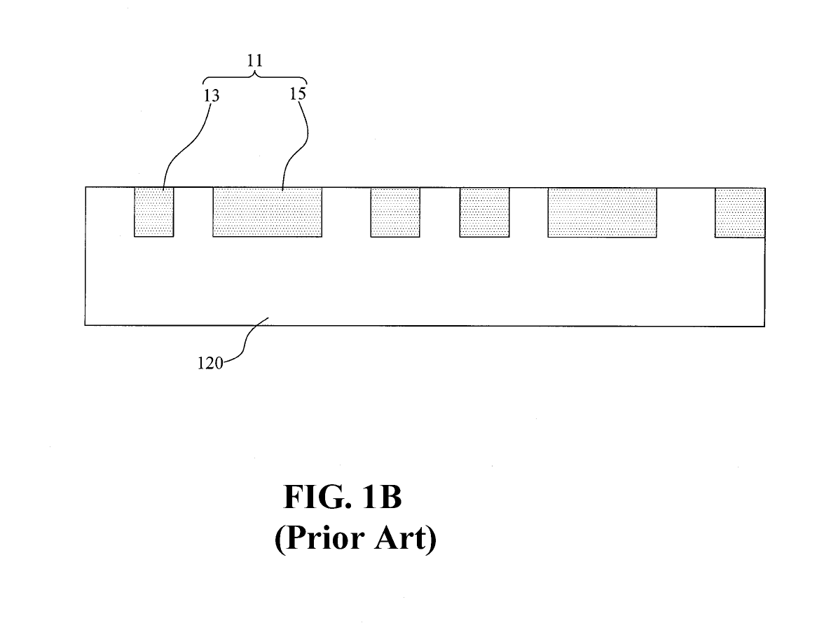

FIG. 2A is a cross sectional view showing the first embodiment of the circuit board structure for high frequency signals according to the present invention;

FIG. 2B is a cross sectional view showing the second embodiment of the circuit board structure for high frequency signals according to the present invention; and

FIG. 2C is a cross sectional view showing the third embodiment of the circuit board structure for high frequency signals according to the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

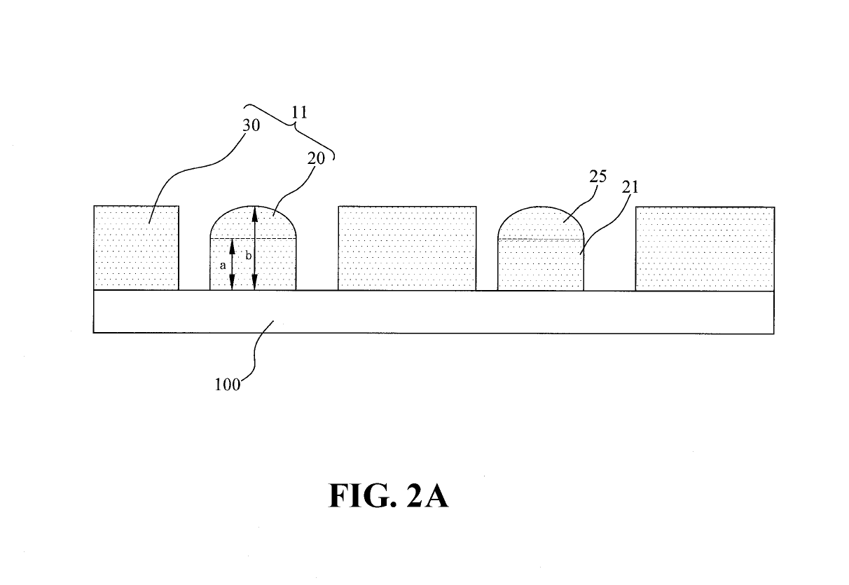

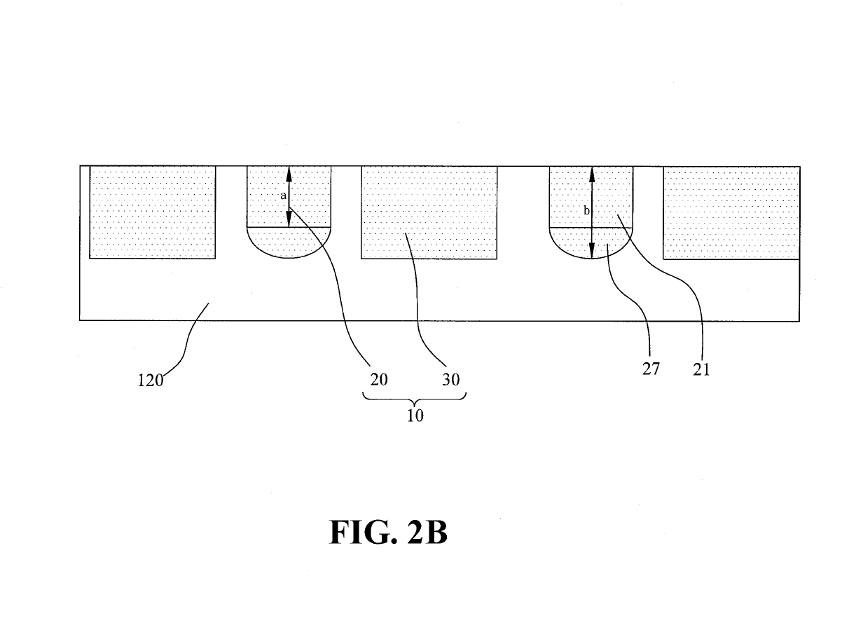

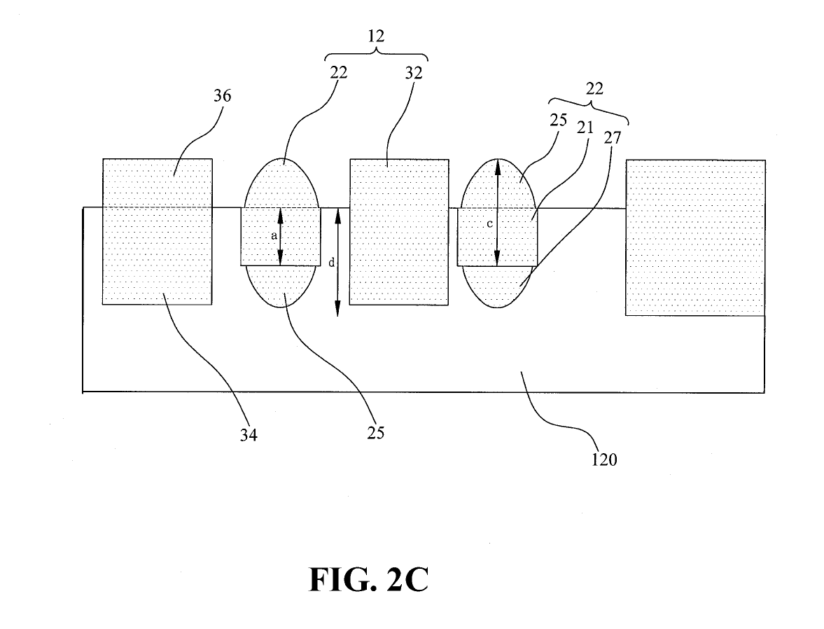

FIG. 2A is a cross sectional view showing the first embodiment of the circuit board structure for high frequency signals according to the present invention. As shown in FIG. 2A, the circuit board structure for high frequency signals of the present invention generally includes the substrate 100 and the electrical conductive circuit layer 10 formed on the substrate 100. The electrical conductive circuit layer 10 includes a plurality of circuit patterns 20 and a plurality of connection pads 30, which are electrically connected to one another (not shown in the cross sectional view of FIG. 2A). Each circuit pattern 20 has the base part 21 and the circular top part 25. The base part 21 is formed of a rectangular block, and the circular top part 25 is provided on the base part 21 and is formed of a hemisphere. The base part 21 and the circular top part 25 are actually integrated as a body. The height of the circuit pattern 20 is b, that of the base part 21 is a, and circuit circularity is defined by (b−a)/a×100%. Preferably, the circuit circularity of the present invention is in a range of 25˜60%.

FIG. 2B is a cross sectional view showing the second embodiment of the circuit board structure for high frequency signals according to the present invention;. The circuit board structure of the second embodiment includes a dielectric plastic film 120 and the electrical conductive circuit layer 10 is embedded in the dielectric plastic film 120 in such a manner to expose to an exterior of the upper surface of the dielectric plastic film 120. Similar to the first embodiment, the electrical conductive circuit layer 10 of the second embodiment includes a plurality of circuit patterns 20 and a plurality of connection pads 30, which are electrically connected to one another (not shown in the cross sectional view of FIG. 2B). Each circuit pattern 20 has the base part 21 and the circular bottom part 27. The base part 21 is formed of a rectangular block, and the circular bottom part 27 is provided beneath the base part 21 and is formed of a hemisphere. Similarly, the base part 21 is incorporated with the circular bottom part 27 as an integrated body. Specifically, the base part 21 is exposed to an exterior of the upper surface of the dielectric plastic film 120. The height of the circuit pattern 20 is b, that of the base part 21 is a, and circuit circularity is defined by (b−a)/a×100%. Preferably, the circuit circularity of the present invention is in a range of 25˜60%.

Further refer to FIG. 2C. As shown in FIG. 2C, the third embodiment of the circuit board structure for high frequency signals according to the present invention includes the dielectric plastic film 120 and the electrical conductive circuit layer 12 embedded in the dielectric plastic film 120 in such a manner that the conductive circuit layer 12 projects from the upper surface of the dielectric plastic film 120. The electrical conductive circuit layer 12 includes a plurality of circuit patterns 22 and a plurality of connection pads 32, which are electrically connected to one another (not shown in the cross sectional view of FIG. 2C). Each circuit pattern 22 has the base part 21, the circular top part 25 and the circular bottom part 27. The base part 21 is formed of a rectangular block, and the circular bottom part 27 is provided beneath the base part 21 and is formed of a hemisphere. The circular bottom part 27 is embedded in the dielectric plastic film 120. The circular top part 25 is formed of a hemisphere and is provided on the dielectric plastic film 120. Specifically, the circular top part 25 projects from the upper surface of the dielectric plastic film 120. The circular top part 25 and the circular bottom part 27 are actually incorporated to form a body. The height of the base part 21 is a, the total height of the circular top part 25 and the base part 21 is c, the total height of the circular bottom part 27 and the base part 21 is d, and the corresponding first circuit circularity is defined by (c˜a)/a×100%, the second circuit circularity is (d−a)/a×100%. Preferably, the first circuit circularity and second circuit circularity of the third embodiment are in a range of 25˜60%.

Additionally, the connection pad 32 in the third embodiment includes the upper connection pad 34 and the lower connection pad 36. The upper connection pad 34 projects from the upper surface of the dielectric plastic film 120, and the lower connection pad 36 is embedded in the dielectric plastic film 120.

One feature of the present invention is that the upper and/or lower part of the circuit pattern are formed of the hemispheres to enhance the optical effect of reflection such that the spike ends causing signal concentration in the prior arts are avoided, and the problem of the signal attenuation is overcome, thereby applying to the signal transmission for high frequency at high speed.

Although the present invention has been described with reference to the preferred embodiments, it will be understood that the invention is not limited to the details described thereof Various substitutions and modifications have been suggested in the foregoing description, and others will occur to those of ordinary skill in the art. Therefore, all such substitutions and modifications are intended to be embraced within the scope of the invention as defined in the appended claims.

1. A circuit board structure for high frequency signals, comprising:
a substrate; and
an electrical conductive circuit layer formed on the substrate and including a plurality of circuit patterns and a plurality of connection pads, each of the plurality of circuit patterns having a base part connected to a circular top part, the base part having a uniform width, the circular top part having a shape of an upper hemisphere with a largest horizontal cross section at a bottom of the upper hemisphere where the base part is connected;
wherein, the circuit patterns are electrically connected to the connection pads, the largest horizontal cross section of the upper hemisphere has a diameter no greater than the uniform width, and the circular top part is incorporated with the base part as an integrated body.

2. The circuit board structure as claimed in claim 1, wherein each circuit pattern has a circuit circularity of 25˜60%, the circuit circularity is defined by (b−a)/a×100%, a is a height of the base part, and b is a height of the circuit pattern.

3. A circuit board structure for high frequency signals, comprising:
a dielectric plastic film; and
an electrical conductive circuit layer embedded in the dielectric plastic film, exposed to an upper surface of the dielectric plastic film, and including a plurality of circuit patterns and a plurality of connection pads, each of the plurality of circuit patterns having a base part connected to a circular bottom part, the base part being exposed to the upper surface and having a uniform width, the circular bottom part having a shape of a lower hemisphere with a largest horizontal cross section at a top of the lower hemisphere where the base part is connected;
wherein, the circuit patterns are electrically connected to the connection pads, the largest horizontal cross section of the lower hemisphere has a diameter no greater than the uniform width, and the circular bottom part is incorporated with the base part as an integrated body.

4. The circuit board structure as claimed in claim 3, wherein each circuit pattern has a circuit circularity of 25˜60%, the circuit circularity is defined by (b−a)/a×100%, a is a height of the base part, and b is a height of the circuit pattern.

5. A circuit board structure for high frequency signals, comprising:
a dielectric plastic film; and
an electrical conductive circuit layer embedded in the dielectric plastic film, projecting to an upper surface of the dielectric plastic film, and including a plurality of circuit patterns and a plurality of connection pads, each of the plurality of circuit patterns having a base part connected to a circular top part and a circular bottom part, the circular bottom part and the base part being embedded in the dielectric plastic film, the circular top part having a shape of an upper hemisphere protruding from the upper surface with a largest horizontal cross section at a bottom of the upper hemisphere where the base part is connected, the base part having a uniform width, the circular bottom part having a shape of a lower hemisphere with a largest horizontal cross section at a bottom of the lower hemisphere where the base part is connected;
wherein the circuit patterns are electrically connected to the connection pads, the largest horizontal cross section of the upper hemisphere has a diameter no greater than the uniform width, the largest horizontal cross section of the lower hemisphere has a diameter no greater than the uniform width, and the circular top part and the circular bottom part are incorporated with the base part as an integrated body.

6. The circuit board structure as claimed in claim 5, wherein each of the circuit patterns has a first circuit circularity and a second circuit circularity, the first circuit circularity and the second circuit circularity are 25˜60%, the first circuit circularity is defined by (c−a/a)×100%, total height of the circular top part and the base part, the second circuit circularity is defined by (d−a)/a×100%, a is a height of the base part, c is a total height of the circular top part and the base part, and d is a total height of the circular bottom part and the base part.

7. The circuit board structure as claimed in claim 5, wherein each of the connection pads includes an upper connection pad and a lower connection pad, the upper connection pad protrudes from the upper surface of the dielectric plastic film, and the lower connection pad is embedded in the dielectric plastic film.
